(19) United States
(12) Patent Application Publication
(10) Pub. No.: US 2022/0011374 A1
(43) Pub. Date: Jan. 13, 2022

(54) METHOD FOR DETERMINING AN AGEING FUNCTION OF AN ACCUMULATOR

(71) Applicant: Commissariat à l'énergie atomique et aux énergies alternatives, Paris (FR)

(72) Inventors: Laurent VINIT, Grenoble Cedex 09 (FR); Maxime MONTARU, Grenoble Cedex 09 (FR)

(73) Assignee: Commissariat à l'énergie atomique et aux énergies alternatives, Paris (FR)

(21) Appl. No.: 17/305,527

(22) Filed: Jul. 9, 2021

(30) Foreign Application Priority Data
Jul. 9, 2020 (FR) 20 07309

(51) Int. Cl. G01R 31/392; G01R 31/367; G01R 31/3832

(52) U.S. Cl. CPC G01R 31/392; G01R 31/3832; G01R 31/367

(57) ABSTRACT

A method for determining an ageing function of an accumulator, the ageing function representing a variation in the capacity or resistance of the accumulator, as a function of variables representative of the operation of the accumulator, the method including carrying out a plurality of experimental cycles of charging and discharging a test accumulator, each cycle being parameterised by accumulator operating parameters that vary as a function of time during the various cycles; b) during experimental cycles, determining experimental data, including a value of each variable parameter, and determining the capacity or the resistance; c) on the basis of the experimental data resulting from b), determining the ageing function of the accumulator; wherein in step a), the variable parameters include the state of charge and a depth of discharge, such that, following step c), the variables of the ageing function with the state of charge and the depth of discharge.

### TECHNICAL FIELD

The technical field of the invention is prediction of the state of health of a battery.

### PRIOR ART

Batteries store energy in chemical form. They have undergone substantial development, and are used in various types of application, in electric vehicles such as electric cars or electric 2-wheelers for example. In this type of application, batteries of lithium-ion accumulators are an attractive option. However, in this type of application, the accumulators undergo a high number of charging-discharging cycles. Requirements in respect of reliability require the ageing mechanisms of batteries to be well understood.

Battery ageing has:
a component that is time-dependent, i.e. due to the passage of time, and that is usually designated by the terms “calendar degradation” or “calendar ageing”;
a component that is use-dependent, i.e. due to the various charging and discharging cycles to which the battery is subjected. This component is usually designated by the terms “cycling degradation” or “cycling ageing”.

Certain operating parameters are considered to have a predominant effect on cycling degradation. These are for example temperature, the total charge exchanged by the battery during the various cycles, or the variation as a function of time in state of charge. The publication Gewald T. “Accelerated aging characterization of Lithium-ion cells: using sensitivity analysis to identify the stress factors relevant to cyclic aging”, Batteries 2020, 6, 6, describes the main parameters having any influence on cycling degradation.

Ageing results in a decrease in the capacity of the battery. It may be quantified by an indicator called state of health (SOH), the latter being representative of a variation in the capacity of the battery between an initial time and a time subsequent to the initial time. The state of health of the battery is usually quantified by a ratio between the capacity, at a given time, and the initial capacity of the battery. It may also be quantified by a ratio between the resistance, at a given time, and the initial resistance of the battery, or by a ratio of remaining discharge energy.

Analysis of the influence of operating parameters on ageing generally involves an experimental phase, in which an accumulator, or group of accumulators, is electrically connected to a testbed. It is thus possible to measure the state of health of the battery as a function of a profile of use of the battery, this profile corresponding to various successive cycles of charging or discharging.

In order to be able to predict ageing, it is useful to obtain an ageing function, allowing the ageing to be estimated as a function of various operating parameters. The publication Sarakesta-Zabala et Al., “Cycle ageing analysis of a LiFePO4/graphite cell with dynamic model validations: towards realistic lifetime predictions”, Journal of power sources 275 (2015) 573-587, for example describes the establishment of an ageing function quantifying ageing as a function of total depth of discharge and of the total charge having flown through the battery.

The inventors have observed certain limits to the use of the ageing function mentioned in the preceding paragraph. They propose another approach, which is considered to be more accurate and simpler to use.

### SUMMARY OF THE INVENTION

A first subject of the invention is a method for determining an ageing function of an accumulator, or of a group of accumulators, the ageing function representing a variation in the capacity or resistance of the accumulator, or of the group of accumulators, as a function of variables representative of the operation of the accumulator, the method comprising:
a) carrying out a plurality of experimental cycles of charging and discharging at least one test accumulator representative of the accumulator or of the group of accumulators, each cycle being parameterised by accumulator operating parameters that vary as a function of time during the various cycles;
b) during the charging and discharging cycles, at various measurement times, determining experimental data comprising a value of each variable parameter;
c) on the basis of the experimental data resulting from b), determining the ageing function;
wherein:
   in step c), the variable parameters comprise at least the state of charge and a depth of discharge, such that, following step c), the variables of the ageing function comprise at least the state of charge and the depth of discharge.

Thus, the ageing function depends both on the state of charge and the depth of discharge at various times, during charging/discharging cycles.

By ageing function, what is meant is a function representative of a variation in the capacity or in the resistance of the accumulator. The ageing function may have a cycling-ageing component, and optionally a calendar-ageing component.

The ageing function may determine:
a decrease in the capacity of the accumulator, or of the group of accumulators, during a use of the accumulator;
or an increase in the resistance of the accumulator, or of the group of accumulators, during the use of the accumulator.

According to one embodiment, the variables of the ageing function comprise, apart from the depth of discharge and the state of charge: temperature and/or charging or discharging current and/or the total charge exchanged by the accumulator. The variables of the ageing function may be at least the charging or discharging current, the state of charge and the depth of discharge.

According to one embodiment, step c) is implemented by an optimisation algorithm, so as to minimise a deviation between:
the capacity or resistance, of the or of each test accumulator, at a plurality of measurement times;
an estimate, determined by applying the ageing function, of the capacity or resistance of the or of each test accumulator at each measurement time.

Preferably, the method comprises, at various measurement times of a given cycle, or even of each cycle, determining a depth-of-discharge value. The method may be such that, the measurement times being classified in chronological order from an initial time, the method comprises, for each measurement time subsequent to two measurement times following the initial time:
comparing the state of charge at the measurement time with the respective states of charge at the preceding measurement time and the penultimate measurement time;
when the comparison indicates that the state of charge varies monotonically, upwards or downwards, between the penultimate measurement time and the measurement time, incrementing the value of the depth of discharge at the measurement time, depending on the value of the depth of discharge at the preceding measurement time;
when the comparison does not indicate that the state of charge varies monotonically, upwards or downwards, between the penultimate measurement time and the measurement time, resetting the value of the depth of discharge at the measurement time.

According to one embodiment:
steps a) and b) may be implemented using successively different test accumulators;
each charging/discharging cycle extends between an initial charge, and a final charge, defining a depth of discharge of the cycle;
at least two different test accumulators are subjected to charging cycles defining a different total depth of discharge.

Preferably, at least two different test accumulators are subjected to charging cycles the initial charge and the final charge of which are different.

A second subject of the invention is a method for estimating the ageing of an accumulator, the method comprising the following steps:
i) determining a model of use of the accumulator, the model of use defining:
   cycles of charging and discharging the accumulator during a duration of use of the accumulator;
   operating parameters of the accumulator during each cycle;
ii) segmenting the duration of use into estimation times;
iii) determining operating parameters at each estimation time;
iv) taking into account an ageing function, the ageing function being a function that for example represents a variation in the capacity or in the resistance of the accumulator as a function of variables;
v) successively applying the ageing function at each estimation time, so as to estimate an ageing of the accumulator, for example a variation in the capacity or in the resistance of the accumulator under the effect of the model of use;
the method being characterised in that:
   the variables of the ageing function are at least the state of charge and the depth of discharge;
   step iii) comprises computing the state of charge and the depth of discharge at each estimation time.

The ageing function may be established by implementing a method according to the first subject of the invention.

According to one embodiment, the estimation times are classified in chronological order from an initial estimation time; the method comprises, at each estimation time subsequent to two estimation times after the initial time:
comparing the state of charge at the estimation time with the respective states of charge at the preceding estimation time and the penultimate estimation time;
when the comparison indicates that the state of charge varies monotonically, upwards or downwards, between the penultimate estimation time and the estimation time, incrementing the value of the depth of discharge at the estimation time, depending on the value of the depth of discharge at the preceding estimation time;
when the comparison does not indicate that the state of charge varies monotonically, upwards or downwards, between the penultimate estimation time and the estimation time, resetting the value of the depth of discharge at the estimation time.

A third subject of the invention is a device for modelling the ageing of an accumulator, the device comprising a processing unit configured to:
take into account a model of use of the accumulator, the model of use defining:
   cycles of charging and discharging the accumulator during a duration of use of the accumulator;
   operating parameters of the accumulator during each cycle;
implement steps ii) to v) of a method according to the second subject of the invention.

The invention will be better understood on reading the description of the exemplary embodiments, which are described, in the rest of the description, with reference to the figures listed below.

### FIGURES

FIG. 1A schematically shows a battery of accumulators.

FIG. 1B shows a testbed intended to receive an accumulator or a group of accumulators.

FIG. 2A shows the main steps of a method for determining an ageing function of an accumulator.

FIG. 2B details a step of determining a depth of discharge at a measurement time.

FIG. 2C shows the main steps of a method for estimating the ageing of an accumulator on the basis of an ageing function established beforehand.

FIG. 3A shows a variation in a capacity of an accumulator as a function of the total charge exchanged by the accumulator, during various charging/discharging cycles, the capacities being measured and simulated, respectively. The simulated capacities were obtained using an ageing function not taking into account the depth of discharge.

FIG. 3B shows relative errors between measured and estimated capacities shown in FIG. 3A.

FIG. 3C shows a variation in a capacity of an accumulator as a function of the total charge exchanged by the accumulator, during various charging/discharging cycles, the capacities being measured and simulated, respectively. The simulated capacities are obtained using an ageing function one variable of which is the depth of discharge.

FIG. 3D shows relative errors between measured and estimated capacities shown in FIG. 3C.

FIGS. 4A and 4B are representations of ageing functions, the variables of which are the state of charge and the depth of discharge, respectively.

### DESCRIPTION OF PARTICULAR EMBODIMENTS

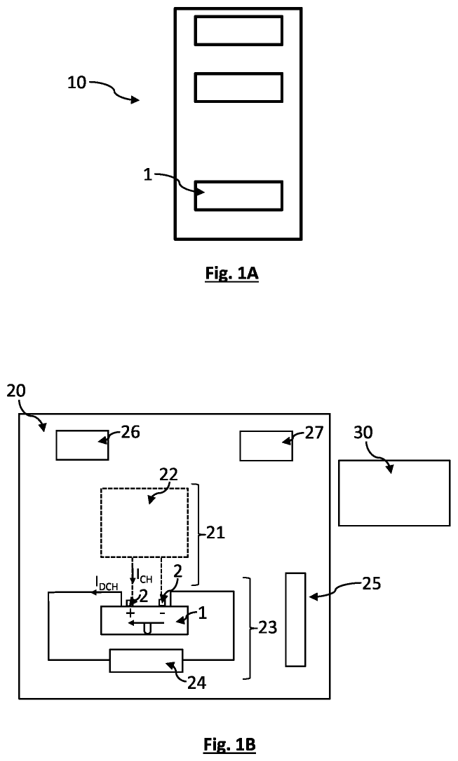

FIG. 1A shows a battery 10 formed from a group of accumulators 1. Each accumulator 1 comprises an electrolyte connected to two electrodes. The accumulator defines a reversible electrochemical system, allowing a conversion between chemical energy and electrical energy and vice versa. In the example shown, the accumulator is of lithium-iron type, the electrolyte being an organic solvent based on lithium salt.

As described with reference to the prior art, it is useful to evaluate the ageing of the battery, notably as a function of a foreseeable employment of the battery. To this end, one accumulator of the battery, or a group of accumulators, is subjected to experimental trials, so as to determine a function representative of an ageing of the accumulator or of the group of accumulators.

As described with reference to the prior art, ageing of an accumulator results in a gradual decrease in capacity, or in a gradual increase in resistance. At a time t, the capacity C(t) corresponds to the amount of charge obtained on a complete discharge of the accumulator. It is usually expressed in Ah (amp hours). Ageing results in a variation in the storage capacity ΔC(t), from an initial capacity C₀. It may also result in a variation in the resistance of the accumulator ΔR(t), from an initial resistance R₀.

In the detailed example that follows, the ageing function corresponds to a variation in capacity during use of the accumulator. The invention also covers the establishment and use of an ageing function corresponding to a variation in resistance during use of the accumulator.

As described with reference to the prior art, an accumulator generally undergoes calendar ageing, which is time-dependent, and which may be expressed by the expression:

$$\frac{d ( Δ C ( t ) )}{dt} = \frac{g ( T ( t ) , SOC ( t ) )}{1 + A Δ C ( t )} \qquad ( 1 )$$

where:
SOC(t), acronym of state of charge, is the state of charge, which corresponds to the amount of charge available in the accumulator, at a time t, relative to the capacity of the battery. The value of SOC(t) is comprised between 0% and 100%. During charging, the state of charge is an increasing function. During discharging, the state of charge is a decreasing function;
T(t) is an operating temperature of the battery;
g is an empirical function, dependent on temperature and on state of charge;
A is a positive constant, sometimes designated the form factor.

The quantity

$$\frac{d ( Δ C ( t ) )}{dt}$$

corresponds to an accumulator-degradation rate that is related to calendar ageing. It may be expressed in Ah·s⁻¹.

The accumulator also undergoes cycling ageing, which may be expressed by the expression:

$$\frac{d ( Δ C ( t ) )}{{dQ}_{tot}} = \frac{h ( T ( t ) , SOC ( t ) , I ( t ) )}{1 + A Δ C ( t )} \qquad ( 2 )$$

where:
I(t) is the magnitude of the charging or discharging current at a time t;
Qₜₒₜ(t) is the total charge passed by the accumulator during the various successive charging and discharging cycles, from an initial time, to the time t;
h Is an empirical function, dependent on the operating temperature, on the state of charge and on the magnitude of the charging or discharging current of the accumulator.

The quantity

$$\frac{d ( Δ C ( t ) )}{{dQ}_{tot}}$$

corresponds to an accumulator-degradation rate that is related to cycling ageing, i.e. that is dependent on the total charge exchanged by the accumulator. Expression (2) shows that capacity variation, magnitude of the current, total charge exchanged and temperature are usually considered to be the parameters that have the most influence on the cycling ageing of the accumulator.

On the basis of (1) and (2), it is possible to predict a variation in the capacity of the accumulator, according to the expression:

$$Δ C ( t ) = \frac{d ( Δ C ( t ) )}{dt} dt + \frac{d ( Δ C ( t ) )}{{dQ}_{tot}} {dQ}_{tot} \qquad ( 3 )$$

The empirical functions g and h are generally obtained experimentally, using a testbed. FIG. 1B schematically shows a testbed 20 intended to place an accumulator, or a group of accumulators, in various states of charge, which are determined in advance, and to measure operating parameters of the accumulator or of the group of accumulators. In the rest of the description, it is assumed that the testbed comprises one accumulator, even though it may comprise a group of accumulators. The various states of charge follow a time-dependent employment profile comprising various successive charging and discharging cycles, and optionally resting phases. Measurement of operating parameters during the cycles allows the empirical functions g and h to be defined experimentally.

The testbed 20 comprises a charging circuit 21, intended to supply a charging current I_{CH} to the accumulator during each charging cycle. The charging circuit 21 comprises an electrical power supply 22 that generates the charging current I_{CH}. The testbed 20 also comprises a discharging circuit 23 through which a discharging current I_{DCH} of the battery flows. The discharging circuit comprises, in this example, a resistor 24.

The testbed 20 comprises an electrical measurement circuit 25 configured to measure a magnitude and/or a voltage of the electrical current flowing between terminals 2 of the accumulator. The testbed also comprises a temperature sensor 26.

The testbed comprises a control unit 27 allowing the charging and discharging cycles of the accumulator to be controlled. The control unit may be an industrial computer allowing trial results to be viewed and stored.

The testbed 20 is connected to a processing unit 30, which is configured to implement the invention. The processing unit comprises a microprocessor. The processing unit is configured to parameterise the charging/discharging cycles of the accumulator, and to establish an ageing function of the accumulator from the operating parameters measured during the charging and discharging cycles. The processing unit 30 also allows operating parameters to be estimated from the data measured by the testbed 20. It is for example a question of state of charge, the latter being determined from the capacity of the accumulator and from the magnitude of the charging or discharging current. It is also a question of the total charge exchanged by the accumulator. According to one possibility, the state of charge and the exchanged total charge are estimated directly by the measurement circuit 25.

During each charging/discharging cycle, the testbed 20 allows operating parameters of the accumulator 1 to be regularly measured. Thus, at various measurement times t, subsequent to an initial time t₀, the testbed 20 allows the operating parameters to be measured, as described below. From the measurements taken by the testbed, the empirical functions g and/or h are obtained.

The inventors have observed that it is preferable for the cycling ageing of an accumulator to be expressed as a function of the state of charge SOC(t), but also as a function of the depth of discharge DOD (t), at various times t. The depth of discharge DOD(t) corresponds:
during a discharge, to the percentage of the charge having been delivered by the accumulator;
during a charge, to the percentage of the charge having been delivered to the accumulator.

Thus, starting with (2), the cycling ageing may be expressed such that:

$$\frac{d ( Δ C ( t ) )}{{dQ}_{tot}} = \frac{h ( T , SOC , I , DOD )}{1 + A Δ C ( t )} \qquad ( 4 )$$

According to this approach, the ageing function, i.e. the function

$$\frac{d ( Δ C ( t ) )}{{dQ}_{tot}} ,$$

comprises an empirical function h(T, SOC, I, DOD) the variables of which are temperature, state of charge, charging or discharging current, and the depth of discharge.

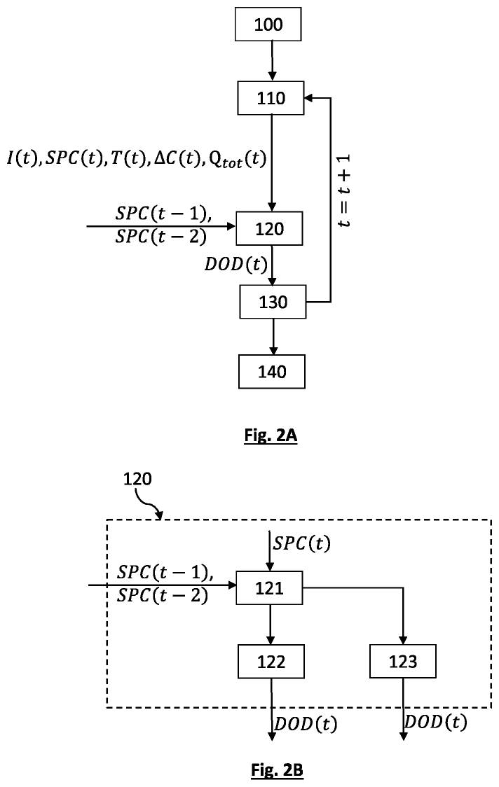

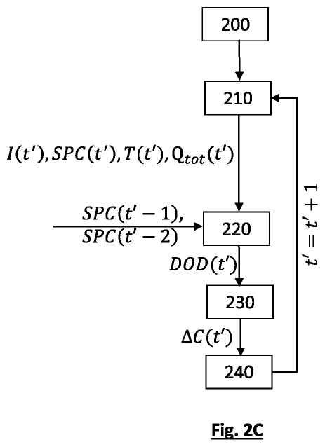

The ageing function may be established experimentally, by following the steps described with reference to FIGS. 2A and 2B. To this end, a test accumulator connected to a testbed 20 such as described with reference to FIG. 1B is used. The test accumulator is representative of the type of accumulator the ageing of which it is desired to study. It is subjected to various charging and discharging cycles. The objective is to obtain the empirical function h, taking into account, at various times of each cycle, both at least the state of charge SOC and the depth of discharge DOD.

Step 100: Initialising. This step is implemented at an initial time t₀. In this step, an employment profile is defined, which corresponds to various charging and discharging cycles of the accumulator and certain operating parameters of the accumulator, temperature for example.

Each charge and each discharge may be parameterised by an initial state of charge SOC(tᵢₙᵢₜ) and a final state of charge SOC(t_{end}). During a charge or a discharge, the total depth of discharge DODₜₒₜ corresponds to the absolute value of the difference between the initial state of charge and the final state of charge: Thus,

DODₜₒₜ=|SOC(tᵢₙᵢₜ)−SOC(t_{end})| (5)

In the experimental phase, which is carried out on the testbed, it is preferable for the employment profile, to which the accumulator is subjected, to be such that:
the initial state of charge SOC(tᵢₙᵢₜ) of the various charges and discharges is variable;
and/or the final state of charge SOC(t_{end}) of the various charges and discharges is variable;
the total depth of discharge DODₜₒₜ of the various charges and discharges is variable.

Preferably, trials are carried out using successively various test accumulators, the latter being representative of the accumulator that it is desired to characterise. A given test accumulator is preferably subjected to charging/discharging cycles between the same initial state of charge and the same final state of charge, this resulting in the same total depth of discharge. Various test accumulators are subjected to various cycles, the initial state of charge and/or the final state of charge and/or the total depth of discharge being modified between two different test accumulators.

Steps 110 and 120 are implemented at various measurement times t, during the charges and discharges. Two successive measurement times t, t+1 may be spaced apart from each other by a duration generally comprised between a few seconds, 10 s for example, and a few minutes.

Step 110: measuring operating parameters at each measurement time.

At each measurement time t accumulator operating parameters, which form variables of the ageing function, are determined using the testbed. It is especially a question of I(t), SOC(t), T(t). It is assumed that during a given charging/discharging cycle, the capacity C(t) of the accumulator remains constant. From the measured values of current I(t), the operating parameters SOC(t), Qₜₒₜ(t) are computed. The capacity C(t) is checked periodically.

Step 120: determining the depth of discharge DOD(t) at the measurement time t.

This step assumes knowledge of the two preceding states of charge, i.e. the states of charge at the times t-1 and t-2. Thus, the implementation of step 120 assumes that step 110 has been implemented at a least two times prior to the measurement time t. In this step, from the state of charge SOC(t), determined at the measurement time t, and from the states of charge SOC(t-1), and SOC(t-2), the depth of discharge DOD(t) is determined.

Step 120 comprises substeps 121 to 123, which are schematically shown in FIG. 2B.

In the substep 121, a direction of variation of the state of charge is determined. It is a question of determining whether the accumulator is being charged, or discharged, or is in a transitory state between a charge and a discharge or in a rest state.

Step 121 comprises a comparison of the states of charge at the times t, t-1 (last time before the time t) and t-2 (penultimate time). When the states of charge, considered in chronological order, follow a monotonic function, whether an increasing or decreasing one, the accumulator is undergoing either a charge, or a discharge:
when SOC(t-2)<SOC(t-1)<SOC(t) (6), the state of charge is following an increasing function, this corresponding to a charge;
when SOC(t-2)>SOC(t-1)>SOC(t) (7), the state of charge is following a decreasing function, this corresponding to a discharge.

When one of conditions (6) and (7) is met, a step 122 of updating the depth of discharge DOD(t) is carried out, according to the expression:

DOD(t)=DOD(t-1)+|SOC(t)−SOC(t-1)| (8)

When neither of conditions (6) and (7) is met, a step 123 of resetting the depth of discharge DOD(t) is carried out, according to the expression:

DOD(t)=|SOC(t)−SOC(t-1)| (9)

It will be noted that during a charge or during a discharge, the depth of discharge is an increasing function, expression (8) implying that DOD(t)>DOD(t-1).

Step 120 allows the depth of discharge to be determined at each measurement time.

### Step 130: Reiterating

In this step, the measurement time t is incremented. Steps 110 to 120 are then repeated to the end of the iterations. The end of the iterations may correspond to the end of the employment profile to which the accumulator is subjected in the testbed.

### Step 140: Optimising

At the end of the iterations, at each measurement time, parameters T(t), SOC(t), DOD(t), Qₜₒₜ(t), I(t) and ΔC(t) are obtained. An optimisation algorithm allows an empirical function h to be determined, such that:

$$\frac{d ( Δ C )}{{dQ}_{tot}} = \frac{h ( T , SOC , I , DOD )}{1 + A Δ C} \qquad ( 10 )$$

The optimisation algorithm may also estimate a value of the constant A. The optimisation algorithm allows a deviation respectively between the measured values of

$$\frac{d ( Δ C ( t ) )}{{dQ}_{tot}}$$

and the values of

$$\frac{d ( Δ C ( t ) )}{{dQ}_{tot}}$$

estimated via expression (10) to be minimised. The optimisation algorithm may be a recursive algorithm, such as a recursive-least-squares or Kalman filter. It may also be a question of a machine-learning algorithm, such as a neural network.

The empirical function h may be of a form that is predetermined, on the basis of a model of the battery, relating the voltage across the terminals of the battery, the state of charge and the charging or discharging current.

Alternatively, the empirical function h is determined, for various values that the operating parameters T, SOC, I and DOD take during the experimental charging/discharging cycles. The method may comprise an interpolating phase in which the empirical function h is determined between various values of a given parameter.

At the end of step 140, an ageing function

$$\frac{d ( Δ C )}{{dQ}_{tot}}$$

representative of the cycling ageing of the battery is obtained.

According to one variant, the ageing function is expressed by a product of two empirical functions h₁ and h₂, according to the expression (10′):

$$\frac{d ( Δ C )}{{dQ}_{tot}} = \frac{{h}_{1} ( T , SOC , I ) {h}_{2} ( T , DOD )}{1 + A Δ C} \qquad {( 10 )}^{′}$$

Steps 100 to 140 correspond to a method for determining the cycling ageing function

$$\frac{d ( Δ C )}{{dQ}_{tot}} .$$

The latter may be combined with a calendar ageing function, such as expressed in expression (1), so as to obtain an estimation of a variation in the capacity of the accumulator, according to expression (3).

It is then possible to estimate an ageing of the accumulator depending on various conditions of use. The conditions of use are defined depending on the operating parameters of the battery: temperature, states of charge, and charging or discharging current. The conditions of use, and the ageing function, are input data of the estimation. The estimating method thus comprises the following steps (see FIG. 2C) .

Step 200: defining the conditions of use: number of cycles, and minimum and maximum states of charge of each cycle. The defined use lies in a time range of use, in which the charging and discharging cycles occur.

Step 205: segmenting the estimation into various estimation times t′, during the time range of use.

Steps 210 to 230 are implemented iteratively, at each estimation time t′.

Step 210: at each estimation time t′, defining operating parameters of the accumulator as a function of the conditions of use defined in step 200. The operating parameters are for example I(t), SPC(t′), T(t′), Qₜₒₜ(t′).

Step 220: determining the depth of discharge DOD(t′) at each estimation time t′. Step 220 is similar to step 120 described with reference to FIGS. 2A and 2B, the measurement times t being replaced by estimation times t′.

Step 230: depending on the operating parameters, which include the depth of discharge, at each estimation time t′, determining a variation in the capacity of the accumulator using the ageing function.

Step 240: incrementing the estimation time t′, until an exit from the algorithm. The algorithm is exited from at the last estimation time, at the end of the time range of use.

In the example described above, the ageing function represents a variation in the capacity of an accumulator. The invention also applies to a group of accumulators or other types of ageing functions.

It is known that the ageing of an accumulator, or of a group of accumulators, results in an increase in resistance. Thus, according to one variant, the ageing function expresses a variation in resistance as a function of time (calendar ageing) and as function of the cycles of charging and discharging of the accumulator (cycling ageing). The variation in resistance due to cycling ageing may be modelled as described with reference to steps 100 to 140. It may then be implemented, for the purposes of prediction, as described with reference to steps 200 to 240.

### Experimental Trials.

The inventors have successively placed test accumulators, representative of an accumulator of a lithium-ion battery, in a Digatron testbed, in order to perform endurance trials. The temperature of the accumulator was kept constant at 45° C. During various trials, the test accumulators were subjected to various charging/discharging cycles the parameters of which are listed in Table 1.

TABLE 1

| Trial | | | |
|---|---|---|---|
| reference | SOCmin (%) | SOCmax (%) | DOD (%) |
| 1 | 47.5 | 52.5 | 5 |
| 2 | 0 | 40 | 40 |
| 3 | 40 | 70 | 30 |
| 4 | 70 | 100 | 30 |
| 5 | 0 | 100 | 100 |

Each charge was carried out in a C/2 charging regime, this meaning that the accumulator was completely recharged in 2 hours. Each discharge was carried out in a 1C regime, this meaning that the accumulator was completely discharged in 1 hour.

During each trial, two ageing functions were determined: an ageing function established without taking into account the depth of discharge, according to expression (2), and an ageing function a variable of which was the depth of discharge measured during each cycle, according to expression (10). The ageing function taking into account depth of discharge was established by following steps 100 to 140 described above, so as to obtain an ageing component due to cycling.

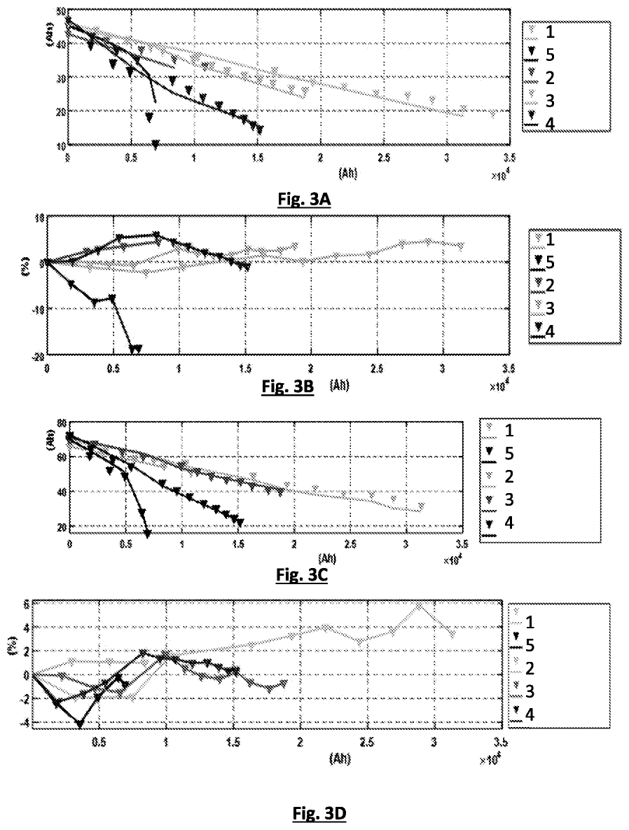

FIG. 3A shows, for each trial, variations respectively in the measured capacity (discrete marks) and the capacity modelled by an ageing function not taking into account depth of discharge. The x-axis corresponds to the total charge Qₜₒₜ exchanged by the accumulator (unit Ah) whereas the y-axis corresponds to the capacity C of the accumulator (unit Ah). FIG. 3B shows the variation in the relative capacity-estimation error as a function of the total charge Qₜₒₜ exchanged by the accumulator. The relative estimation error, expressed in %, corresponds to a comparison between the capacity C of the accumulator as estimated by the ageing function, and the actually measured capacity. The comparison is normalised by the measured capacity.

FIG. 3C shows, for each trial, variations respectively in the measured capacity (discrete marks) and the capacity modelled by an ageing function the variables of which comprise both state of charge and depth of discharge. The x-axis corresponds to the total charge Qₜₒₜ exchanged by the accumulator (unit Ah) whereas the y-axis corresponds to the capacity C of the accumulator (unit Ah). FIG. 3D shows the variation in the relative capacity-estimation error as a function of the total charge Qₜₒₜ exchanged by the accumulator, such as described with reference to FIG. 3B.

FIGS. 3A and 3C show that the degradation trajectory, i.e. the variation in capacity as a function of the exchanged total charge, depends both on depth of discharge and on the minimum and maximum states of charge of each cycle. The trials referenced 3 and 4 correspond to the same depth of discharge (30%) but respectively different minimum and maximum states of charge, 40%-70% and 70%-100% respectively. The degradation trajectory respectively associated with trials 3 and 4 is however significantly different. This shows that it is appropriate for the ageing function to depend on both state of charge and depth of discharge.

Moreover, comparison of FIGS. 3B and 3D shows that, when an ageing function dependent on state of charge and depth of discharge is used, the estimation error is significantly decreased, for each trial carried out. The variation in the capacity of the battery is estimated more accurately, this attesting to the relevance of the approach followed by the inventors.

Thus, taking into account the depth of discharge and the state of charge, at different measurement times in each cycle allows a better evaluation of the cycling aging. Although the depth of discharge and the state of charge are quantities related to each other by an additive relationship, the cycling aging function is defined by combining these two variables. The combination is defined empirically, and not by a simple analytical relationship.

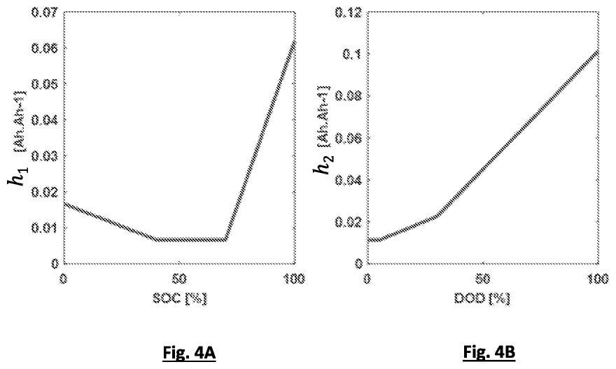

During the implementation of the trials, the inventors established empirical functions h₁ and h₂ such as described with reference to expression (10′). The product of the empirical functions h₁ and h₂ corresponds to the empirical function h described with reference to steps 100 to 140. FIGS. 4A and 4B show various values respectively taken by the functions h₁ and h₂ for a given charging current, as a function of state of charge (x-axis of FIG. 4A) and of depth of discharge (x-axis of FIG. 4B), respectively.

The function h₁ is an empirical function such as described in expression (2). The function h₂ may be considered to be a correction applied to the function h₁, so as to take into account the depth of discharge when establishing the ageing function.

In practice, an empirical function h, such as described above, may be represented in a space the dimension of which depends on the number of variables. In the described experimental example, temperature was kept constant. The empirical function h then depends on 3 variables, corresponding to the charging and discharging current (the charging current being of opposite sign to the discharging current), the state of charge and the depth of discharge.

The invention will possibly be employed to parameterise battery management systems (BMSs), so as to predict and optimise the lifetime of batteries. Although described, in this example, in relation to a lithium-ion battery, the invention may be applied to other types of batteries.

1. A method for determining an ageing function of an accumulator, or of a group of accumulators, the ageing function representing a variation in the capacity or resistance of the accumulator, or of the group of accumulators, as a function of variables representative of the operation of the accumulator, the method comprising:
a) carrying out a plurality of experimental cycles of charging and discharging at least one test accumulator representative of the accumulator or of the group of accumulators, each cycle being parameterised by accumulator operating parameters that vary as a function of time during the various cycles;
b) during the charging and discharging cycles, at various measurement times, determining experimental data comprising a value of each variable parameter;
c) on the basis of the experimental data resulting from b), determining the ageing function;
wherein:
b) comprises determining the state of charge and a depth-of-discharge value, at various measurement times of a given cycle, the depth of discharge value at each measurement time being determined from a difference between the state of charge at the measurement time and a state of charge at a preceding measurement time;
in c), the variable parameters comprise at least the state of charge and a depth of discharge, such that, following c), the variables of the ageing function comprise at least the state of charge and the depth of discharge.

2. The method according to claim 1, wherein the ageing function determines:
a decrease in the capacity of the accumulator, or of the group of accumulators, during a use of the accumulator;
or an increase in the resistance of the accumulator, or of the group of accumulators, during the use of the accumulator.

3. The method according to claim 2, wherein the variables of the ageing function comprise, apart from the depth of discharge and the state of charge: temperature and/or charging or discharging current and/or the total charge exchanged by the accumulator.

4. The method according to claim 3, wherein the variables of the ageing function are at least the charging or discharging current, the state of charge and the depth of discharge.

5. The method according to claim 1, wherein c) is implemented by an optimisation algorithm, so as to minimise a deviation between:
a capacity or resistance, of the or of each test accumulator, measured at a plurality of measurement times;
an estimate, determined by applying the ageing function, of the capacity or resistance of the or of each test accumulator at each measurement time.

6. The method according to claim 1, wherein the measurement times are classified in chronological order from an initial time, the method further comprising, for each measurement time subsequent to two measurement times following the initial time:
comparing the state of charge at the measurement time with the respective states of charge at the preceding measurement time and the penultimate measurement time;
when the comparing indicates that the state of charge varies monotonically, upwards or downwards, between the penultimate measurement time and the measurement time, incrementing the value of the depth of discharge at the measurement time, depending on the value of the comparing depth of discharge at the preceding measurement time;
when the comparing does not indicate that the state of charge varies monotonically, upwards or downwards, between the penultimate measurement time and the measurement time, resetting the value of the depth of discharge at the measurement time.

7. The method according to claim 1, wherein:
a) and b) are implemented using successively different test accumulators;
each charging/discharging cycle extends between an initial charge, and a final charge, defining a depth of discharge of the cycle;
at least two different test accumulators are subjected to charging cycles defining a different total depth of discharge.

8. The method according to claim 7, wherein at least two different test accumulators are subjected to charging cycles the initial charge and the final charge of which are different.

9. A method for estimating the ageing of an accumulator, comprising:
i) determining a model of use of the accumulator, the model of use defining:
cycles of charging and discharging the accumulator during a duration of use of the accumulator;
operating parameters of the accumulator during each cycle;
ii) segmenting the duration of use into estimation times;
iii) determining operating parameters at each estimation time;
iv) taking into account an ageing function, the ageing function representing a variation in the capacity or in the resistance of the accumulator as a function of variables;
v) successively applying the ageing function at each estimation time so as to estimate a variation in the capacity or in the resistance of the accumulator under the effect of the model of use;
wherein:
the variables of the ageing function are at least the state of charge and the depth of discharge;
iii) comprises computing the state of charge and the depth of discharge at each estimation time.

10. The method according to claim 9, wherein the ageing function is established.

11. The method according to claim 9, wherein, the estimation times are classified in chronological order from an initial estimation time, the method further comprising, at each estimation time subsequent to two estimation times after the initial time:
comparing the state of charge at the estimation time with the respective states of charge at the preceding estimation time and the penultimate estimation time;
when the comparing indicates that the state of charge varies monotonically, upwards or downwards, between the penultimate estimation time and the estimation time, incrementing the value of the depth of discharge at the estimation time, depending on the value of the depth of discharge at the preceding estimation time;
when the comparing does not indicate that the state of charge varied monotonically, upwards or downwards, between the penultimate estimation time and the estimation time, resetting the value of the depth of charge at the estimation time.

12. A device for modelling the ageing of an accumulator, the device comprising a processing unit configured to:
take into account a model of use of the accumulator, the model of use defining:
cycles of charging and discharging the accumulator during a duration of use of the accumulator;
operating parameters of the accumulator during each cycle;
implement steps ii) to v) of a method according to claim 9.
